(19) United States
(12) Patent Application Publication
(10) Pub. No.: US 2009/0090955 A1
(43) Pub. Date: Apr. 9, 2009

(54) ELEVATED CHANNEL FLASH DEVICE AND MANUFACTURING METHOD THEREOF

(75) Inventors: Jer-Chyi Wang, Taoyuan County (TW); Ming-Cheng Chang, Taipei County (TW); Yi-Feng Chang, Taipei County (TW); Wei-Ming Liao, Taipei City (TW); Chien-Chang Huang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 12/057,391

(22) Filed: Mar. 28, 2008

(30) Foreign Application Priority Data
Oct. 3, 2007 (TW) 96137072

(51) Int. Cl. H01L 21/336; H01L 29/788

(52) U.S. Cl. 257/316; 438/257; 257/E29.3; 257/E21.409

(57) ABSTRACT

A FLASH device including a substrate having a protrusive portion integrally formed thereon, two floating gates, a control gate and a dielectric layer is provided. The two floating gates are disposed on two sides of the protrusive portion and respectively covering a portion of the protrusive portion. The control gate is disposed on top of the protrusive portion and sandwiched between the two floating gates. The dielectric layer is disposed between each of the two floating gates and the control gate. Because the control gate of the FLASH device is disposed on the protrusive portion, an elevated channel can be formed. Moreover, because of the position of the two floating gates, an effective floating gate (FG) length can be increased without impacting the cell density.

### CROSS-REFERENCE TO RELATED APPLICATION

This application claims the priority benefit of Taiwan application serial no. 96137072, filed on Oct. 3, 2007. The entirety the above-mentioned patent application is hereby incorporated by reference herein and made a part of specification.

### BACKGROUND OF THE INVENTION

1. Field of the Invention

The present invention relates to a FLASH device technology. More particularly, the present invention relates to a FLASH device having an elevated channel and a manufacturing method thereof.

2. Description of Related Art

In various kinds of non-volatile memories, an electrically erasable programmable read-only memory (EEPROM), capable of saving programmed information without being limited by the ON/OFF of the power supply, has been widely used by personal computers and electronic devices. A non-volatile memory called “flash memory” has become one of the important memory elements on the market, due to the mature technology and low cost.

Generally, the flash memory is formed by sequentially stacking a tunneling oxide layer, a floating gate, a dielectric layer, and a control gate on a substrate. However, as the element becomes increasingly small, the current flash memory cell is also continuously improved. Recently, a “FinFET-like FLASH” has been developed, which is like a FinFET field effect transistor structure, in which a control gate is fabricated to erect on a flat substrate like a fin, and floating gates are disposed on two sides of the FinFET-like control gate.

However, the channel length of the FinFET-like FLASH is small due to the small device size and the structure, so the operating voltage range (or cell window) of the memory cells becomes very narrow. Therefore, the operating voltage range of the cells must be expanded by increasing the programming voltage or pulse width, which, however, will lead to the reliability issue and low operation speed. In addition, the cell density will be impacted if the operating voltage range of the cells is expanded by increasing the channel length.

### SUMMARY OF THE INVENTION

Accordingly, the present invention is directed to a FLASH device having an elevated channel, which increases an effective floating gate length without impacting cell density.

The present invention is also directed to a manufacturing method of a FLASH device, which increases an effective floating gate length without impacting cell density, and improves an operating voltage range (or cell window) of cells.

The present invention is further directed to a manufacturing method of a FLASH device, which increases an effective floating gate length, improves an operating voltage range of cells, and improves a coupling ratio.

As embodied and broadly described herein, the present invention provides a FLASH device, which includes a substrate having a protrusive portion integrally formed thereon, two floating gates, a control gate, and a dielectric layer. The floating gates are respectively disposed on two sides of the protrusive portion. A portion of a top surface of the protrusive portion is covered with the floating gates. The control gate is disposed on top of the protrusive portion and sandwiched between the two floating gates. The dielectric layer is disposed between each of the two floating gates and the control gate.

In one embodiment of the present invention, a top surface of the control gate has a first height and a top surface of each of the two floating gates has a second height shorter than the first height of the control gate.

In one embodiment of the present invention, the top surface of the control gate laterally extends in two opposite directions to cover the top ends of the two floating gates.

In one embodiment of the present invention, the substrate further includes a plurality of isolation structures and a protrusion formed on the substrate and sandwiched between two of the isolation structures.

In one embodiment of the present invention, the protrusive portion is formed on the protrusion.

In one embodiment of the present invention, the dielectric layer includes an oxide-nitride-oxide (ONO) structure.

The present invention further provides a manufacturing method of a FLASH device, which includes providing a substrate having a plurality of parallel isolation structures therein and a protrusive portion formed between two of the parallel isolation structures, and forming a first conductive material on two opposite sides of the protrusive portion on the substrate respectively. Next, a dielectric layer is conformally formed to cover the protrusive portion, the first conductive material, and then a second conductive material is partially sandwiched by the first conductive material and covering a portion of the dielectric layer.

In another embodiment of the present invention, the method of forming the protrusive portion includes partially removing the substrate between the isolation structures, or growing the protrusive portion on the substrate by means of an epitaxy process.

In another embodiment of the present invention, the method of forming the protrusive portion includes growing the protrusive portion on the substrate by means of an epitaxy process.

In another embodiment of the present invention, the first conductive material forming step includes firstly forming a conductive layer on the substrate to cover the protrusive portion and the isolation structures, and then removing the conductive layer above the isolation structures such that the first conductive material is formed and extending toward the first direction.

In another embodiment of the present invention, the manufacturing method further includes partially removing the second conductive material to expose a portion of the dielectric layer above the first conductive material.

In another embodiment of the present invention, the dielectric layer includes an oxide-nitride-oxide structure.

The present invention further provides a manufacturing method of a FLASH device, which includes providing a substrate having a plurality of isolation structures. Then, a protrusive portion is formed on the substrate between the isolation structures, and a first strip of conductor extending toward a first direction and covering the protrusive portion is formed on the substrate between the isolation structures. Then, a dielectric layer is formed on the substrate, and a top of the dielectric layer is at a same level with that of the first strip of conductor. Next, a mask layer covering the dielectric layer and the first strip of conductor is formed on the substrate, and then the mask layer is patterned to expose a portion of the first strip of conductor and the dielectric layer. After that, the exposed first strip of conductor and dielectric layer and a portion of the isolation structures below the dielectric layer are removed by using the patterned mask layer as an etching mask, so as to form a trench extending toward a second direction. Then, an inter-gate dielectric layer is formed on a surface of the trench, and a second strip of conductor is formed to fill the trench. Finally, a portion of the mask layer is removed, so as to retain the mask layer on two sides of the second strip of conductor and expose a portion of the first strip of conductor, and the exposed first strip of conductor is removed.

In still another embodiment of the present invention, the method of forming the protrusive portion includes removing a portion of the substrate between the isolation structures, or growing the protrusive portion on the substrate by means of an epitaxy process.

In still another embodiment of the present invention, the first strip forming step includes firstly forming a first conductive layer on the substrate to cover the protrusive portion and the isolation structures, and then removing the first conductive layer above the isolation structures to form the first strip of conductor extending toward the first direction.

In still another embodiment of the present invention, the second strip forming step includes forming a second conductive layer filling the trench and covering the inter-gate dielectric layer on the substrate, and then the second conductive layer and the inter-gate dielectric layer above the top surface of the mask layer is removed.

In still another embodiment of the present invention, the method of removing a portion of the mask layer includes etching back the mask layer, so as to form a spacer on a side wall of the second strip of conductor.

In still another embodiment of the present invention, the second direction is perpendicular to the first direction.

Because the control gate of the FLASH device of the present invention is disposed on a protrusive portion, an elevated channel can be formed. Meanwhile, the floating gates are respectively disposed on two sides of the protrusive portion, and cover a portion of the top surface of the protrusive portion, so the effective floating gate length can be increased without impacting the cell density. Moreover, the operating voltage range of the cells can be improved and the coupling ratio can be increased according to the method of the present invention.

In order to make the aforementioned and other features and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective structural view of a FLASH device according to a first embodiment of the present invention.

FIG. 2 is a cross-sectional view taken along line segment II-II in FIG. 1.

FIG. 3 is a perspective structural view of a FLASH device according to a second embodiment of the present invention.

FIG. 4 is a cross-sectional view taken along line segment IV-IV in FIG. 3.

FIGS. 5A-5M are perspective views of the process to manufacture a FLASH according to a third embodiment of the present invention.

FIGS. 6A-6E are perspective views of the process to manufacture a FLASH according to a fourth embodiment of the present invention.

### DESCRIPTION OF EMBODIMENTS

The present invention is fully described below with reference to the accompanying drawings. A plurality of embodiments of the present invention is shown in the accompanying drawings. However, the present invention can be implemented through various difference forms, which should not be interpreted as being limited by the embodiments described in the present invention. Practically, the embodiments are provided to make the present invention be more specific and complete, and to fully convey the scope of the present invention to those of ordinary skill in the art. In the drawings, in order to be explicit, the size and relative size of each layer and region may be exaggeratedly shown.

It should be understand that, although “first”, “second”, and other terms may be used in the present invention to describe various elements, regions, layers, and/or portions, the terms are only used to differentiate one element, region, layer, or portion from another, but not to limit the elements, regions, layers, and/or portions. Therefore, without departing from the teaching of the present invention, the above first element, region, layer, or portion can be called a second element, region, layer, or portion.

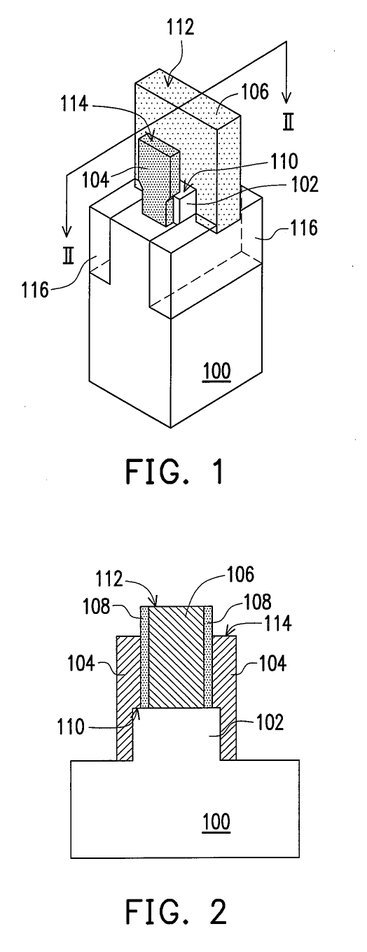

FIG. 1 is a perspective structural view of a FLASH device according to a first embodiment of the present invention, in which some components are not shown for clarity. FIG. 2 is a cross-sectional view taken along line segment II-II in FIG. 1.

Referring to FIGS. 1 and 2, the FLASH device of the first embodiment includes a substrate 100 having a protrusion with a protrusive portion 102, two floating gates 104, a control gate 106, and a dielectric layer 108. The floating gates 104 are respectively disposed on two sides of the protrusive portion 102. A portion of a top surface 110 of the protrusive portion 102 is covered by the floating gates 104. The control gate 106 is disposed on top of the protrusive portion 102 and sandwiched between the floating gates 104. The dielectric layer 108 is disposed between each of the floating gates 104 and the control gate 106. In order to show the relative position of the control gate 106 and the floating gates 104 clearly, the dielectric layer 108 is not shown in FIG. 1. A material of the floating gates 104, for example, is polysilicon or other appropriate materials, a material of the control gate 106, for example, is polysilicon or other appropriate materials, and the dielectric layer 108, for example, is an oxide-nitride-oxide(ONO) structure or made of other appropriate materials.

Referring to FIG. 1 again, a top surface 112 of the control gate 106 has a first height and a top surface 114 of each of the floating gates 104 has a second height shorter than the first height of the control gate 106 in the first embodiment. The substrate 100 of the first embodiment can further include two isolation structures 116 such as shallow trench isolation (STI) structures disposed on two sides of the protrusive portion 102. In addition, the control gate 106 can span the protrusive portion 102 and contact with the isolation structures 116.

Because the control gate 106 of the FLASH device is disposed on the protrusive portion 102 in the first embodiment, an elevated channel can be formed. Moreover, because of the position of the two floating gates 104, an effective floating gate length can be increased without impacting the cell density.

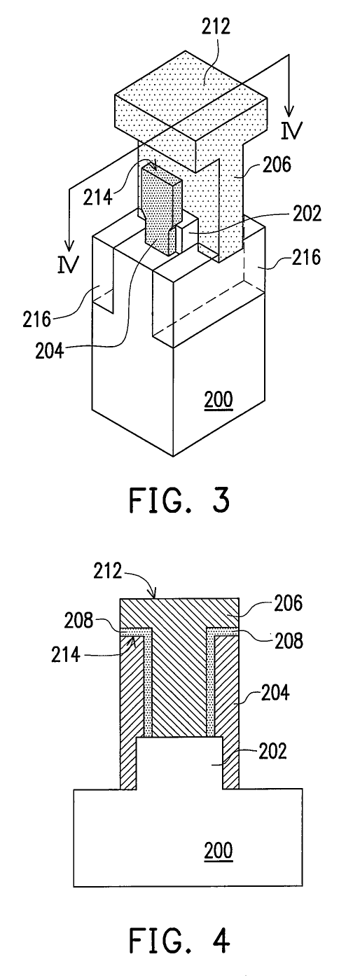

FIG. 3 is a perspective structural view of a FLASH device according to a second embodiment of the present invention, in which some components are not shown. FIG. 4 is a cross-sectional view taken along line segment IV-IV in FIG. 3.

Referring to FIGS. 3 and 4, the FLASH device of the second embodiment includes a substrate 200 having a protrusive portion 202, two floating gates 204, a control gate 206, and a dielectric layer 208. The difference between the first and the second embodiments lies in the shape of the control gate 206. Here, the top surface of the control gate 206 laterally extends in two opposite directions to cover the top ends 214 top ends 214 of the two floating gates 204. Moreover, in order to show the relative position of the control gate 206 and the floating gates 204 clearly, the dielectric layer 208 is not shown in FIG. 3. In addition, FIG. 3 also includes isolation structures 216 and a protrusion formed on the substrate 200 and sandwiched between two of the isolation structures 216. Other conditions of the FLASH device of the second embodiment can be understood with reference to the first embodiment.

As the control gate 206 is a T-shaped gate in the second embodiment, it not only achieves the effects of the first embodiment, but also improves the coupling ratio of the device.

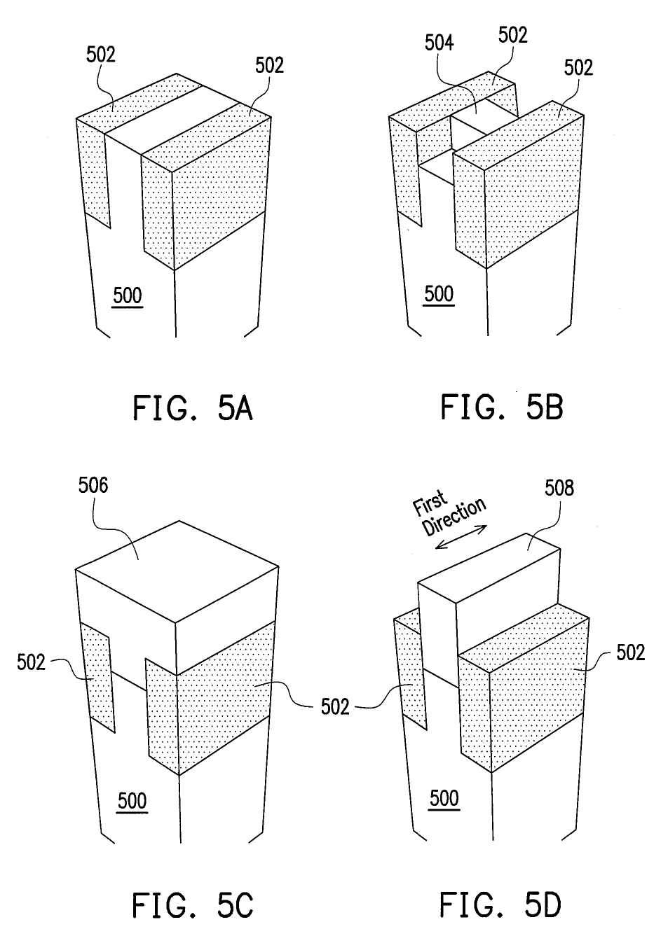

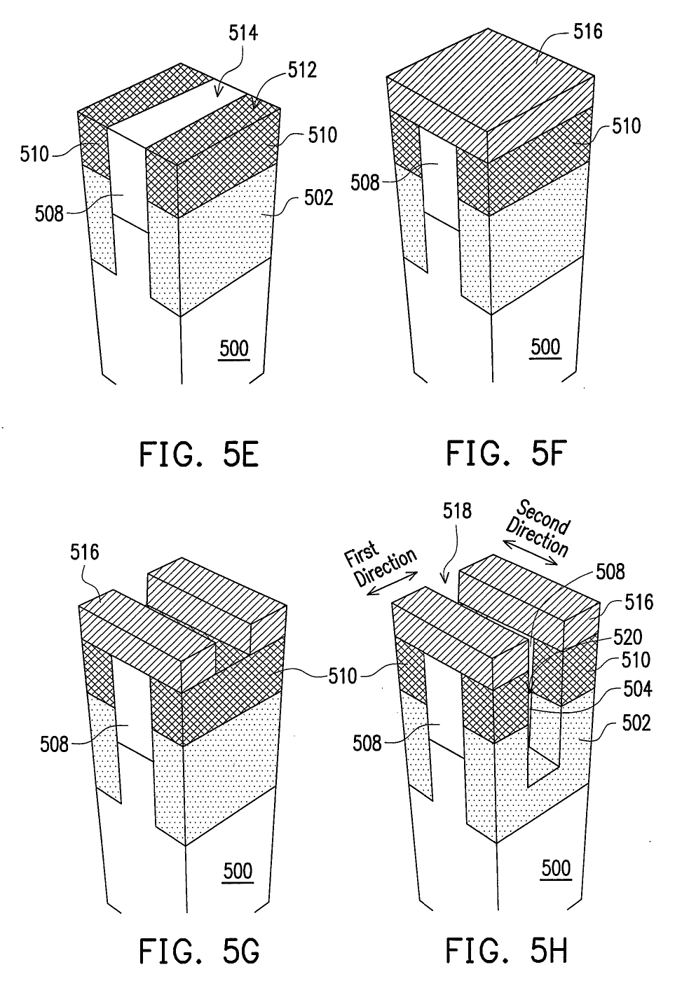

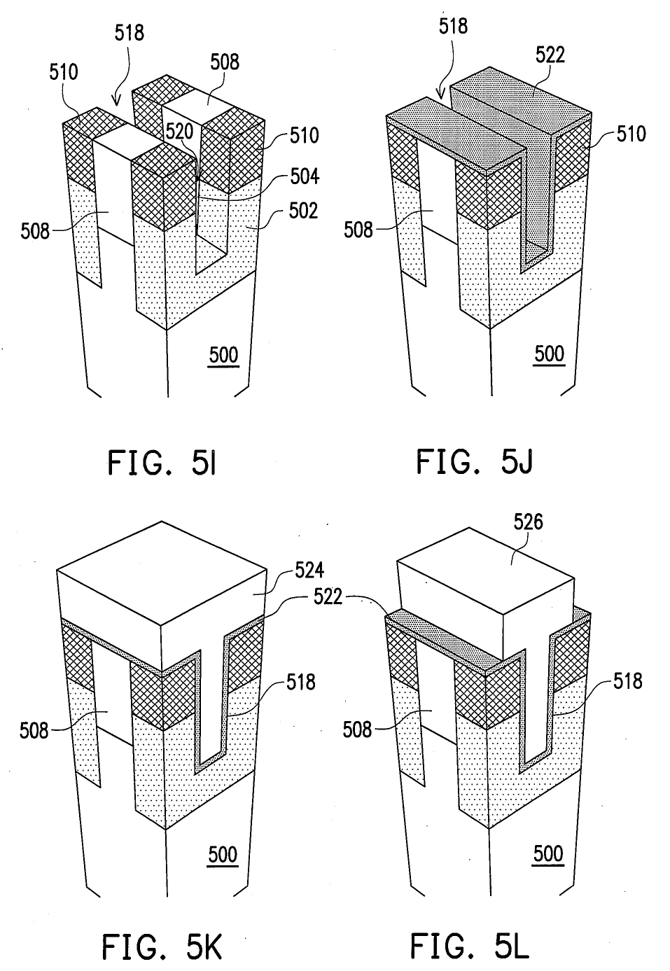

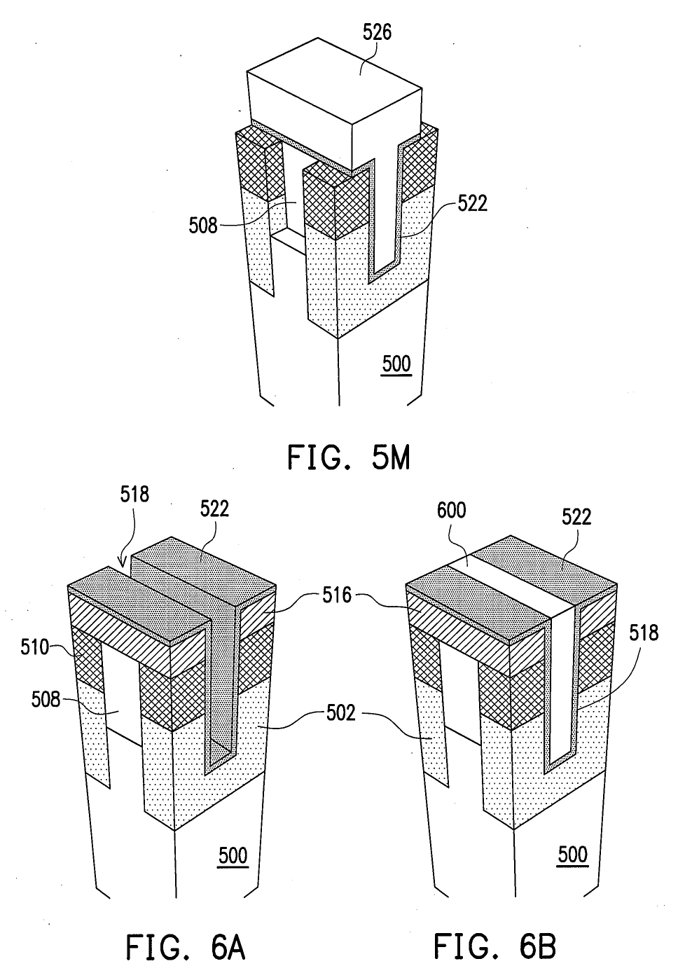

FIGS. 5A-5M are perspective views of the process to manufacture a FLASH device according to a third embodiment of the present invention.

Referring to FIG. 5A, a substrate 500 is provided. The substrate 500 has a plurality of parallel isolation structures 502 such as STI structures.

Then, referring to FIG. 5B, a protrusive portion 504 is formed on the substrate 500 between two of the isolation structures 502. The method of forming the protrusive portion 504 is, for example, partially removing the substrate 500 between the isolation structures 502 as shown in this figure, or growing the protrusive portion on the substrate 500 by means of an epitaxy process.

Next, referring to FIG. 5C, a first conductive layer 506 is formed on the substrate 500 to cover the protrusive portion (not shown) and the isolation structures 502.

Then, referring to FIG. 5D, the first conductive layer above the isolation structures 502 (see 506 of FIG. 5C) is removed, so as to form a first strip of conductor 508 extending toward a first direction and covering the protrusive portion (not shown) on the substrate 500 between the isolation structures 502.

Next, referring to FIG. 5E, a dielectric layer 510 is formed on the isolation structures 502, and a top surface 512 of the dielectric layer 510 is at a same level with a top surface 514 of the first strip of conductor 508.

After that, referring to FIG. 5F, a mask layer 516 is formed on the substrate 500. The mask layer 516 covers the dielectric layer 510 and the first strip of conductor 508, and a material of the mask layer 516 can be photoresist, silicon nitride, or other appropriate materials.

Next, referring to FIG. 5G, the mask layer 516 is patterned to expose a portion of the first strip of conductor 508 and the dielectric layer 510.

Afterward, referring to FIG. 5H, the exposed first strip of conductor 508 and the dielectric layer 510 and a portion of the isolation structures 502 below the dielectric layer 510 are removed by using the patterned mask layer 516 as an etching mask, so as to form a trench 518 extending toward a second direction. The trench 518 exposes a portion of a top surface 520 of the protrusive portion 504, and the second direction is perpendicular to the first direction.

Then, referring to FIG. 5I, the mask layer in FIG. 5H has been removed.

Next, referring to FIG. 5J, an inter-gate dielectric layer 522 covering a surface of the trench 518 and top surfaces of the first strip of conductor 508 and the dielectric layer 510 is formed on the substrate 500. The inter-gate dielectric layer 522, for example, is an ONO structure.

Thereafter, referring to FIG. 5K, in order to form the T-shaped conductive layer, a second conductive layer 524 is formed on the substrate 500 first, so as to fill the trench 518 and cover the inter-gate dielectric layer 522.

Then, referring to FIG. 5L, a portion of the second conductive layer (see 524 in FIG. 5K) is removed to expose a portion of the first conductive layer 508 and the inter-gate dielectric layer 522 above the dielectric layer 510, so as to form a T-shaped conductive layer 526 filling the trench 518 and covering a portion of the inter-gate dielectric layer 522 above the first strip of conductor 508.

Then, referring to FIG. 5M, the exposed inter-gate dielectric layer 522 is removed to expose a portion of the first strip of conductor 508, and then the exposed first strip of conductor 508 is removed.

The manufacturing method of the third embodiment can form the FLASH device with an elevated channel, and can improve the operating voltage range (cell window) of cells.

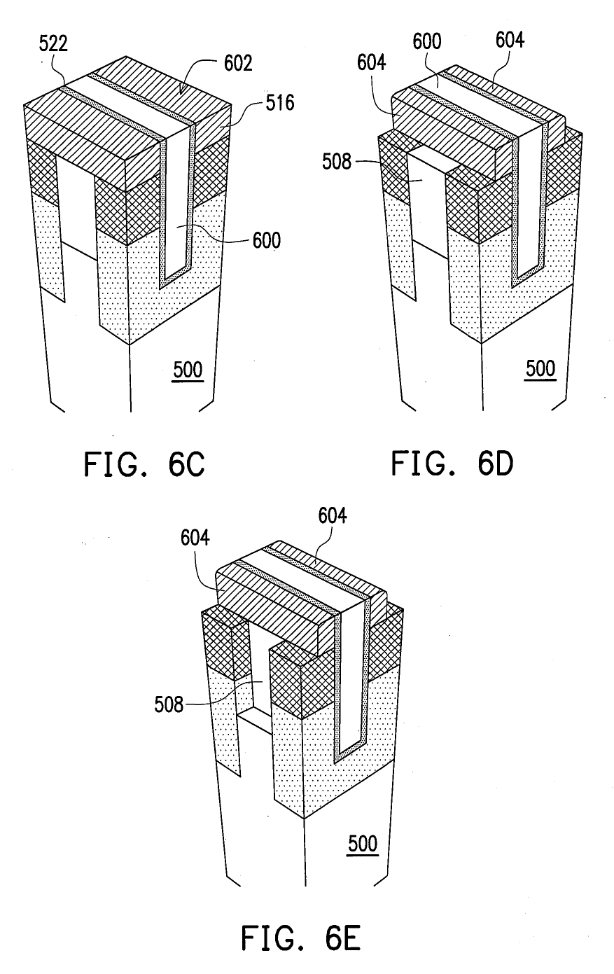

FIGS. 6A-6E are perspective views of the process to manufacture a FEC-FLASH according to a fourth embodiment of the present invention. Here, the first few steps of the fourth embodiment are the same as those described in FIGS. 5A-5H, so the same reference numerals as those of the third embodiment are used to indicate the same or similar devices.

After the steps of FIGS. 5A-5H, a trench 518 is formed in the dielectric layer 510, the first strip of conductor 508, and the isolation structures 502. Then, referring to FIG. 6A, an inter-gate dielectric layer 522 is formed on the surface of the trench 518. At this time, the inter-gate dielectric layer 522 covers the top surface of the mask layer 516.

Next, referring to FIG. 6B, a second strip of conductor 600 is formed to fill the trench 518. The step of forming the second strip of conductor 600 includes, for example, forming a second conductive layer (not shown) on the substrate 500 first, and then removing the second conductive layer above the inter-gate dielectric layer 522.

Next, referring to FIG. 6C, the inter-gate dielectric layer 522 above the top surface 602 of the mask layer 516 is removed.

Then, referring to FIG. 6D, a portion of the mask layer (see 516 of FIG. 6C) is removed to retain the mask layer on two sides of the second strip of conductor 600 and expose a portion of the first strip of conductor 508. The method of removing a portion of the mask layer is, for example, etching back the mask layer, so as to form a spacer 604 on the side wall of the second strip of conductor 600.

Finally, referring to FIG. 6E, the exposed first strip of conductor 508 is removed by using the spacer 604 as a mask.

The manufacturing method of the fourth embodiment can be used not only to form the FLASH device with an elevated channel, but also to directly convert the mask layer 516 to the spacer 604 that is used as the mask when etching the floating gates (i.e., the finally obtained first strip of conductor 508). Therefore, a mask process is omitted.

To sum up, the characteristics of the present invention are that the control gate of the FLASH device is disposed on a protrusive portion of the substrate, so as to form the elevated channel. Moreover, the floating gates are disposed on two sides of the protrusive portion and cover a portion of the top surface of the protrusive portion, so the effective floating gate length can be increased without impacting the cell density. In addition, the manufacturing method of the present invention can be used to form the FLASH device having improved operating voltage range and higher coupling ratio.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A FLASH device comprising:
a substrate having a protrusive portion integrally formed thereon;
two floating gates disposed on two sides of the protrusive portion and respectively covering a portion of a top surface of the protrusive portion;
a control gate disposed on top of the protrusive portion and sandwiched between the two floating gates; and
a dielectric layer disposed between each of the two floating gates and the control gate.

2. The FLASH device as claimed in claim 1, wherein a top surface of the control gate has a first height and a top surface of each of the two floating gates has a second height shorter than the first height of the control gate.

3. The FLASH device as claimed in claim 2, wherein the top surface of the control gate laterally extends in two opposite directions to cover the top surfaces of the two floating gates.

4. The FLASH device as claimed in claim 1, wherein the substrate further comprises a plurality of isolation structures, and a protrusion formed on the substrate and sandwiched between two of the isolation structures.

5. The FLASH device as claimed in claim 4, wherein the protrusive portion is formed on the protrusion.

6. The FLASH device as claimed in claim 1, wherein the dielectric layer comprises an oxide-nitride-oxide structure.

7. A manufacturing method of a FLASH device comprising:
providing a substrate having a plurality of parallel isolation structures therein and a protrusive portion formed between two of the plurality of parallel isolation structures;
respectively forming a first conductive material on two opposite sides of the protrusive portion on the substrate;
conformally forming a dielectric layer to cover the protrusive portion, the first conductive material, and the plurality of isolation structures; and
forming a second conductive material partially sandwiched by the first conductive material and covering a portion of the dielectric layer.

8. The manufacturing method of a FLASH device as claimed in claim 7, wherein the method of forming the protrusive portion comprises partially removing the substrate between the plurality of isolation structures.

9. The manufacturing method of a FLASH device as claimed in claim 7, wherein the method of forming the protrusive portion comprises growing the protrusive portion on the substrate by means of an epitaxy process.

10. The manufacturing method of a FLASH device as claimed in claim 7, wherein the first conductive material forming step comprises:
forming a conductive layer on the substrate to cover the protrusive portion and the plurality of isolation structures; and
removing the conductive layer above the isolation structures such that the first conductive material is formed and extending toward the first direction.

11. The manufacturing method of a FLASH device as claimed in claim 7, further comprising:
partially removing the second conductive material to expose a portion of the dielectric layer above the first conductive material.

12. The manufacturing method of a FLASH device as claimed in claim 7, wherein the dielectric layer comprises an oxide-nitride-oxide structure.

13. A manufacturing method of a FLASH device comprising:
providing a substrate, wherein the substrate has a plurality of isolation structures;
forming a protrusive portion on the substrate between the isolation structures;
forming a first strip of conductor on the substrate between the isolation structures, wherein the first strip of conductor extends toward a first direction and covers the protrusive portion;
forming a dielectric layer on the substrate, wherein a top of the dielectric layer is at a same level with a top of the first strip of conductor;
forming a mask layer on the substrate, wherein the mask layer covers the dielectric layer and the first strip of conductor;
patterning the mask layer to expose a portion of the first strip of conductor and the dielectric layer;
removing the exposed first strip of conductor, the dielectric layer, and the isolation structures by using the patterned mask layer as an etching mask, so as to form a trench extending toward a second direction;
forming a dielectric layer on a surface of the trench;
forming a second strip of conductor to fill the trench;
removing a portion of the mask layer to retain the mask layer on two sides of the second strip of conductor and expose a portion of the first strip of conductor; and
removing the exposed first strip of conductor.

14. The manufacturing method of a FLASH device as claimed in claim 13, wherein the method of forming the protrusive portion comprises removing a portion of the substrate between the isolation structures.

15. The manufacturing method of a FLASH device as claimed in claim 13, wherein the method of forming the protrusive portion comprises growing the protrusive portion on the substrate by means of an epitaxy process.

16. The manufacturing method of a FLASH device as claimed in claim 13, wherein the first strip forming step comprises:
forming a first conductive layer on the substrate to cover the protrusive portion and the isolation structures; and
removing the first conductive layer above the isolation structures to form the first strip of conductor extending toward the first direction.

17. The manufacturing method of a FLASH as claimed in claim 16, wherein the second strip forming step comprises:
forming a second conductive layer on the substrate, wherein the second conductive layer fills the trench and covers the inter-gate dielectric layer; and
removing the second conductive layer and the inter-gate dielectric layer on a top surface of the mask layer.

18. The manufacturing method of a FLASH as claimed in claim 13, wherein the method of removing a portion of the mask layer comprises etching back the mask layer, so as to form a spacer on a side wall of the second strip of conductor.

19. The manufacturing method of a FLASH as claimed in claim 13, wherein the first direction is perpendicular to the second direction.
